(19) United States
(12) Patent Application Publication
(10) Pub. No.: US 2014/0246734 A1
(43) Pub. Date: Sep. 4, 2014

(54) REPLACEMENT METAL GATE WITH MULITIPLE TITANIUM NITRIDE LATERS

(71) Applicant: Globalfoundries Inc., Grand Cayman, KY (US)

(72) Inventors: Hoon Kim, Guilderland, NY (US); Kisik Choi, Hopewell Junction, NY (US)

(73) Assignee: GLOBALFOUNDRIES INC., Grand Cayman (KY)

(21) Appl. No.: 13/782,106

(22) Filed: Mar. 1, 2013

(51) Int. Cl. H01L 29/51; H01L 29/49; H01L 21/28

(52) U.S. Cl. CPC H01L 29/517; H01L 21/28008; H01L 29/4966
USPC 257/410; 438/591

(57) ABSTRACT

A semiconductor comprising a multilayer structure which prevents oxidization of the titanium nitride layer that protects a high-K dielectric layer is provided. Replacement metal gates are over the multilayer structure. A sacrificial polysilicon gate structure is deposited first. The sacrificial polysilicon gate structure is then removed, and the various layers of the replacement metal gate structure are deposited in the space previously occupied by the sacrificial polysilicon gate structure.

### FIELD OF THE INVENTION

The present invention relates generally to semiconductors and, more particularly, to a replacement metal gate and method of fabrication.

### BACKGROUND

In integrated circuit (IC) fabrication, areas in which a metal gate is to exist are oftentimes filled with a dummy gate material that is later replaced with other metal gate materials. The dummy gate material holds the position for the metal gate and prevents damage to the metal gate material that would occur to the metal gate material if it were in place during certain processing. One challenge in replacement metal gate processing is filling the gate area with metal after removal of the dummy gate material.

Some transistors perform functions for circuits in the critical signal path of the IC, where speed is crucial to the proper operation of the IC. In contrast, other transistors perform functions for circuits in the non-critical signal path of the IC, where speed is not as important. Transistors in the non-critical signal path are preferably designed to consume less power than transistors in the critical signal path. Still other transistors may perform functions for a signal path having a criticality somewhere between the critical signal path and the non-critical signal path and, accordingly, have different speed and power consumption requirements.

Due to smaller off-state current leakage, transistors which have higher threshold voltages (Vt) generally consume less power than transistors which have lower threshold voltages. Threshold voltage refers to the minimum gate voltage necessary for the onset of current flow between the source and the drain of a transistor. Transistors which have lower threshold voltages are faster (e.g., have quicker switching speeds) than transistors which have higher threshold voltages.

### SUMMARY OF THE INVENTION

In general, embodiments of the present invention provide an improved replacement metal gate and method of fabrication. In particular, when using high-K dielectrics with gate structures, processing such as densification anneals can damage the high-K dielectric, affecting device variability and product yield. A titanium nitride (TiN) layer may be used to protect the dielectric. While the TiN layer provides protection, it is also prone to oxidization. When the TiN layer becomes oxidized, its work function increases, which in turn increases the threshold voltage of a transistor using the metal gate of an n-type field effect transistor (nFET). The increase in threshold voltage has adverse affects in terms of integrated circuit design, pertaining particularly to switching speed, which benefits from a low threshold voltage (Vt).

Embodiments of the present invention provide a multilayer structure which prevents oxidization of the titanium nitride layer that protects the high-K dielectric. Hence, embodiments of the present invention achieve protection of the dielectric layer, while also maintaining a lower threshold voltage. Replacement metal gates in accordance with embodiments of the present invention may be utilized in both planar devices, as well as fin type devices. A sacrificial polysilicon gate structure may be deposited first to form other transistor elements, such as sources, drains, fins, spacers, and the like. The sacrificial polysilicon gate structure is then removed, and the various layers of the replacement metal gate structure are deposited in the space previously occupied by the sacrificial polysilicon gate structure.

A first aspect of the present invention includes a semiconductor structure, comprising: a semiconductor substrate; a dielectric layer disposed on the semiconductor substrate; an unoxidized titanium nitride layer disposed on the dielectric layer; a barrier layer disposed on the unoxidized titanium nitride layer; and a metal layer disposed on the barrier layer.

A second aspect of the present invention includes a gate structure comprising: an N-type region; a P-type region, wherein the N-type region and the P-type region comprises: a semiconductor substrate; a dielectric layer disposed on the semiconductor substrate; a first titanium nitride layer disposed on the dielectric layer, wherein the first titanium nitride layer is unoxidized; a barrier layer disposed on the first titanium nitride layer; and wherein the N-type region further comprises an N-type metal disposed on the barrier layer; and wherein the P-type region further comprises a second titanium nitride layer disposed on the barrier layer.

A third aspect of the present invention includes a method of fabricating a gate structure, comprising: depositing a dielectric layer on a semiconductor substrate; depositing a first titanium nitride layer on the dielectric layer; depositing a carbon-containing barrier layer on the first titanium nitride layer; depositing a second titanium nitride layer on the carbon-containing barrier layer; removing a portion of the second titanium nitride layer to form an N-type region; and depositing a metal layer in the N-type region.

### BRIEF DESCRIPTION OF THE DRAWINGS

Certain elements in some of the figures may be omitted, or illustrated not to scale, for illustrative clarity. The cross-sectional views may be in the form of “slices”, or “near-sighted” cross-sectional views, omitting certain background lines which would otherwise be visible in a “true” cross-sectional view, for illustrative clarity. Furthermore, for clarity, some reference numbers may be omitted in certain drawings.

Features of this invention will be more readily understood from the following detailed description of the various aspects of the invention taken in conjunction with the accompanying drawings in which:

FIG. 1 is a top-down view of a gate structure in accordance with illustrative embodiments;

FIG. 2 is a semiconductor structure at a starting point for a process in accordance with illustrative embodiments;

FIG. 3A is a semiconductor structure after a subsequent process step of depositing a multilayer stack in accordance with illustrative embodiments;

FIG. 3B shows details of the multilayer stack in FIG. 3A in accordance with illustrative embodiments;

FIG. 4 is a semiconductor structure after a subsequent process step of removing the top sublayer from the N-type region, in accordance with illustrative embodiments;

FIG. 5A is a semiconductor structure after a subsequent process step of depositing a metal layer in the N-type region in accordance with illustrative embodiments;

FIG. 5B is a semiconductor structure after a subsequent process step of depositing a metal layer in the P-type region in accordance with illustrative embodiments;

FIG. 6 is a flowchart indicating process steps in accordance with illustrative embodiments;

FIG. 7 is a planar NFET in accordance with illustrative embodiments;

FIG. 8 is a planar PFET in accordance with illustrative embodiments; and

FIG. 9 is a top-down view of finFETs in accordance with illustrative embodiments.

### DETAILED DESCRIPTION

Exemplary embodiments will now be described more fully herein with reference to the accompanying drawings, in which exemplary embodiments are shown. Exemplary embodiments of the invention provide an improved replacement metal gate and method of fabrication. As part of the FET fabrication process, work function metal patterning is needed. During the work function metal patterning, the high-K dielectric can be exposed to chemicals and plasma, which can damage the high-K dielectric, affecting device variability and product yield. A titanium nitride (TiN) layer may be used to protect the dielectric. A barrier layer, such as tantalum carbide, is disposed on the titanium nitride to prevent oxidation.

It will be appreciated that this disclosure may be embodied in many different forms and should not be construed as limited to the exemplary embodiments set forth herein. Rather, these exemplary embodiments are provided so that this disclosure will be thorough and complete and will fully convey the scope of this disclosure to those skilled in the art. The terminology used herein is for the purpose of describing particular embodiments only and is not intended to be limiting of this disclosure. For example, as used herein, the singular forms “a”, “an”, and “the” are intended to include the plural forms as well, unless the context clearly indicates otherwise. Furthermore, the use of the terms “a”, “an”, etc., do not denote a limitation of quantity, but rather denote the presence of at least one of the referenced items. It will be further understood that the terms “comprises” and/or “comprising”, or “includes” and/or “including”, when used in this specification, specify the presence of stated features, regions, integers, steps, operations, elements, and/or components, but do not preclude the presence or addition of one or more other features, regions, integers, steps, operations, elements, components, and/or groups thereof.

Reference throughout this specification to “one embodiment,” “an embodiment,” “embodiments,” “exemplary embodiments,” or similar language means that a particular feature, structure, or characteristic described in connection with the embodiment is included in at least one embodiment of the present invention. Thus, appearances of the phrases “in one embodiment,” “in an embodiment,” “in embodiments” and similar language throughout this specification may, but do not necessarily, all refer to the same embodiment.

The terms “overlying” or “atop”, “positioned on” or “positioned atop”, “underlying”, “beneath” or “below” mean that a first element, such as a first structure (e.g., a first layer), is present on a second element, such as a second structure (e.g. a second layer), wherein intervening elements, such as an interface structure (e.g. interface layer), may be present between the first element and the second element.

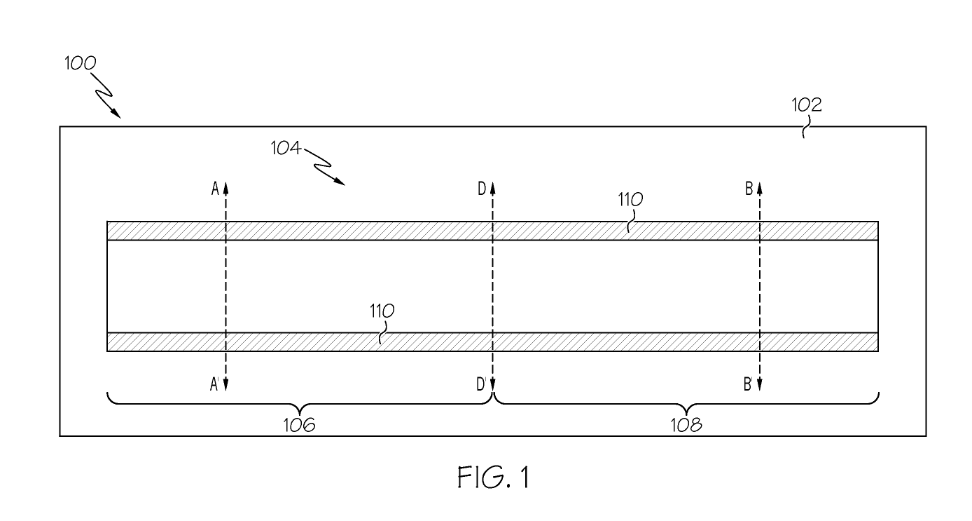

FIG. 1 is a top-down view of a semiconductor structure 100 in accordance with illustrative embodiments. Semiconductor structure 100 comprises a semiconductor substrate 102, which may comprise a bulk silicon substrate, a silicon-on-insulator substrate, or a substrate of another suitable material. Gate structure 104 is disposed on substrate 102. Gate structure 104 comprises an N-type region 106 and a P-type region 108. The N-type region 106 is used to form the gate of an N-type field effect transistor (NFET). The P-type region 108 is used to form the gate of a P-type field effect transistor (PFET). Spacer regions 110 may be disposed adjacent to the gate region 104. The spacer regions 110 may be comprised of nitride, oxide, or other suitable material. Line A-A′ traverses the N-type region 106. Line B-B′ traverses the P-type region 108. Line D-D′ delineates the boundary between the N-type region 106 and the P-type region 108.

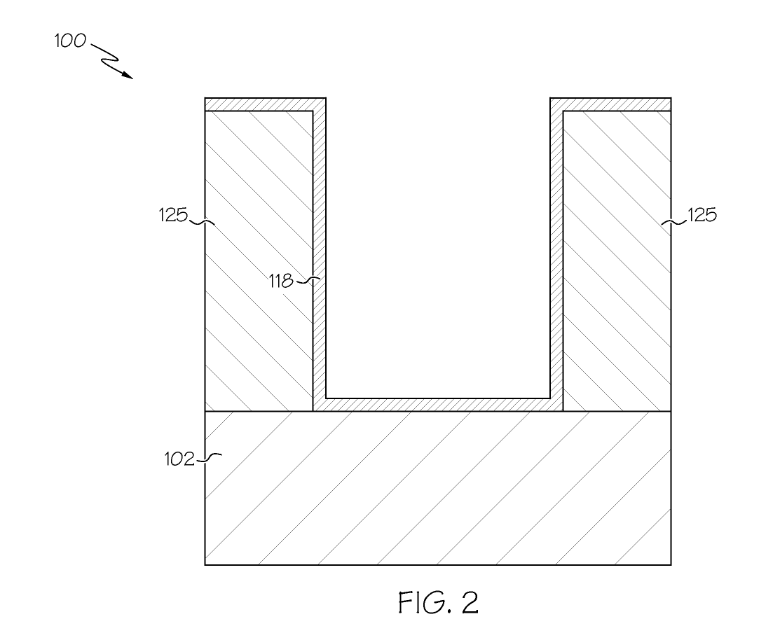

FIG. 2 is a semiconductor structure 100 at a starting point for a process of fabricating the gate structure, as viewed along line A-A′ or B-B′ of FIG. 1. A dielectric layer 118 is deposited via a conformal deposition process in a trench structure formed by dielectric regions 125 and semiconductor substrate 102. Dielectric layer 118 may be a high-K dielectric (k>4). In some embodiments, the dielectric layer 118 is comprised of hafnium oxide. In other embodiments, the dielectric layer 118 is comprised of hafnium and lanthanum oxide. In still other embodiments, additional layers may be present in between layer 118 and the semiconductor substrate 102, such as a silicon oxide layer.

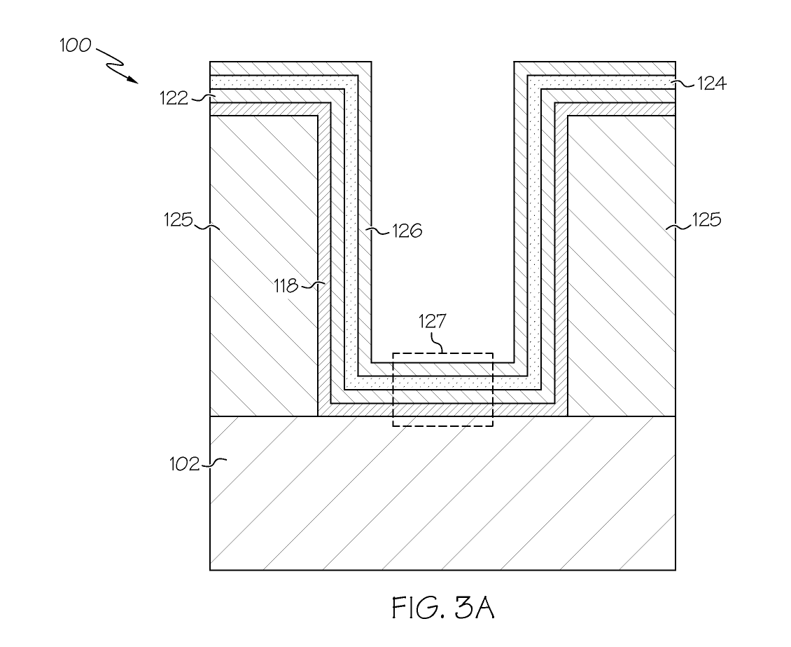

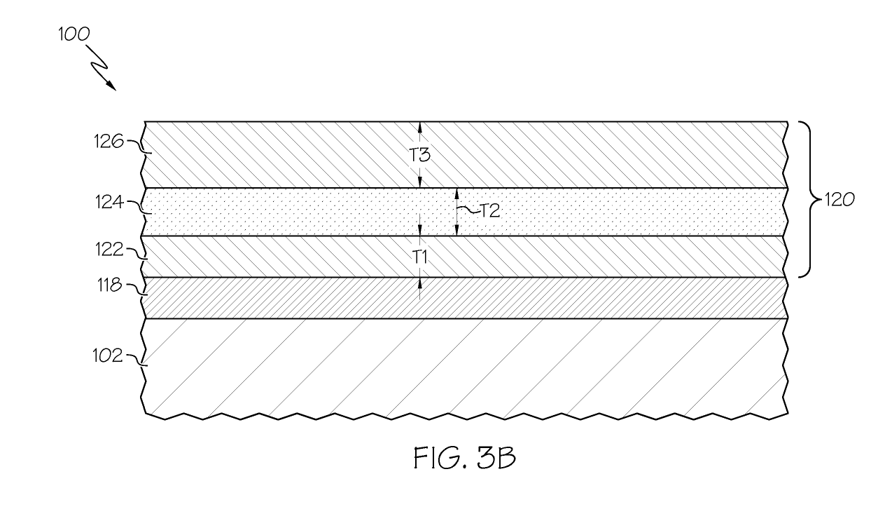

FIG. 3A and FIG. 3B show a semiconductor structure 100, as viewed along line A-A′ or B-B′ of FIG. 1, after a subsequent process step of depositing a multilayer stack 120. FIG. 3B shows details of the area indicated by region 127 of FIG. 3A. Multilayer stack 120 comprises three layers arranged as a “sandwich.” Layer 122 is a first layer of titanium nitride. Layer 124 is a barrier layer. In embodiments, layer 124 is comprised of a carbon-containing material, and may include, but is not limited to, tantalum carbide, and hafnium carbide. It is desirable that the barrier layer 124 be selective to the titanium nitride during etching. Layer 126 is a second layer of titanium nitride, thus making the “sandwich” of two titanium nitride layers with a barrier layer in between them. Layers 122 and 124 may be deposited via atomic layer deposition (ALD) or chemical vapor deposition (CVD). As shown in FIG. 3B, in some embodiments, layer 122 may have a thickness T1 ranging from about 5 angstroms to about 15 angstroms. In embodiments, layer 124 may have a thickness T2 ranging from about 5 angstroms to about 15 angstroms. Layer 126 may have a thickness T3 ranging from about 10 angstroms to about 100 angstroms. In embodiments, layer 126 may be deposited via ALD. In other embodiments, layer 126 may be deposited via chemical vapor deposition (CVD).

Layer 122 has a purpose of protecting the dielectric layer 118 during the fabrication process. In particular, processes such as a densification anneal can damage the dielectric layer, which can cause reliability and yield issues for integrated circuits. The titanium nitride layer 122, deposited prior to such an anneal, serves to protect the dielectric layer 118. However, titanium nitride is prone to oxidation. When titanium nitride is oxidized, its work function is increased, which results in an increased voltage threshold, which may be undesirable in certain applications, such as where high switching speed is desired. By depositing the barrier layer 124 over the titanium nitride layer 122, oxidization of the titanium nitride layer 122 is prevented. Hence, titanium nitride layer 122 is an unoxidized titanium nitride layer. The unoxidized titanium nitride layer 122 does not significantly contribute to an increase in threshold voltage.

Hence, embodiments of the present invention provide unoxidized titanium nitride layer 122, which serves to keep the threshold voltage lower, enabling faster switching times. The second titanium nitride layer 126 serves as the work function metal in the P-type region.

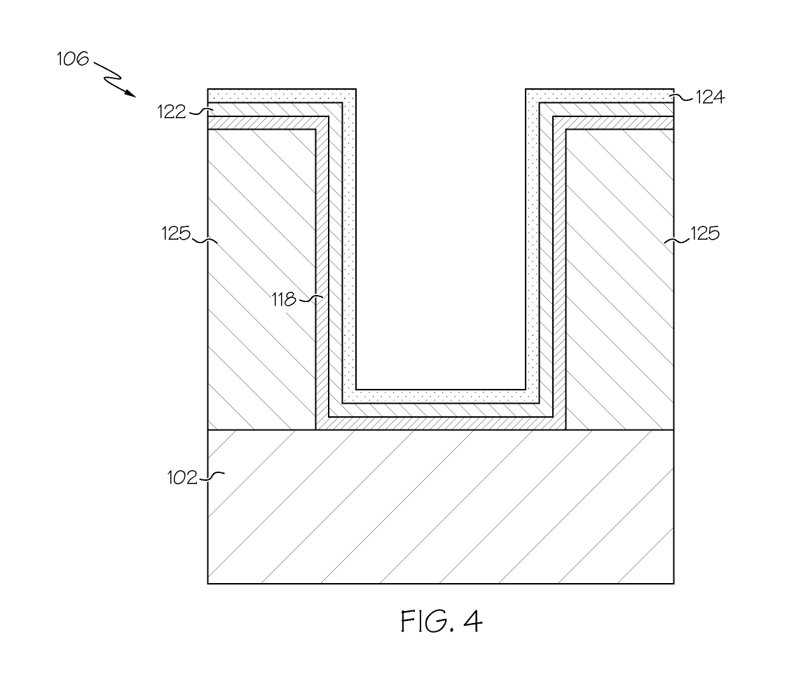

FIG. 4 is semiconductor structure 106 (as viewed along line A-A′ of FIG. 1) after a subsequent process step of removing the second titanium nitride layer 126 from the N-type region 106. As shown in FIG. 4, the barrier layer 124 is exposed over the N-type region 106. The removal of the portion of second titanium nitride layer 126 may be achieved with patterning and etching techniques known in the industry. In some embodiments, a selective reactive ion etch (RIE), or wet etching process is used to remove the portion of second titanium nitride layer 126. A mask (not shown) may be temporarily formed on the P-type region 108 (FIG. 1) to facilitate removal on the N-type region 106.

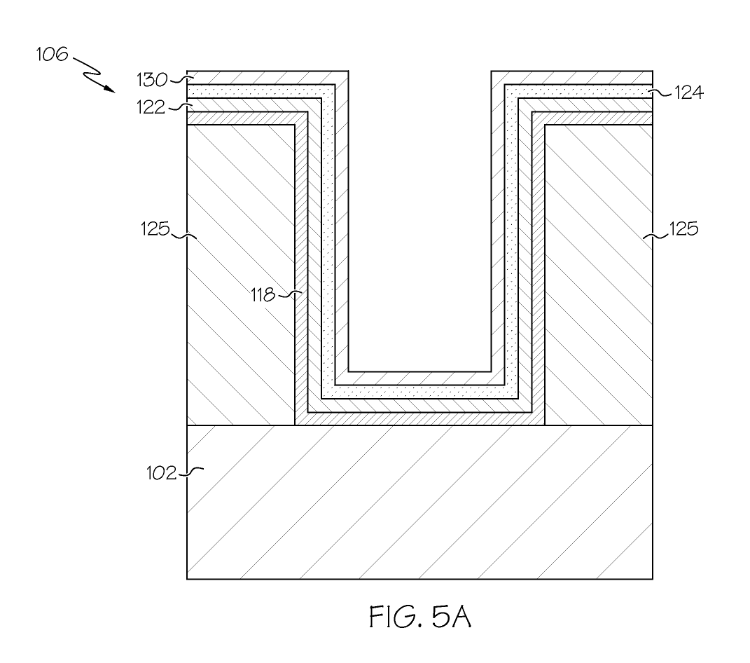

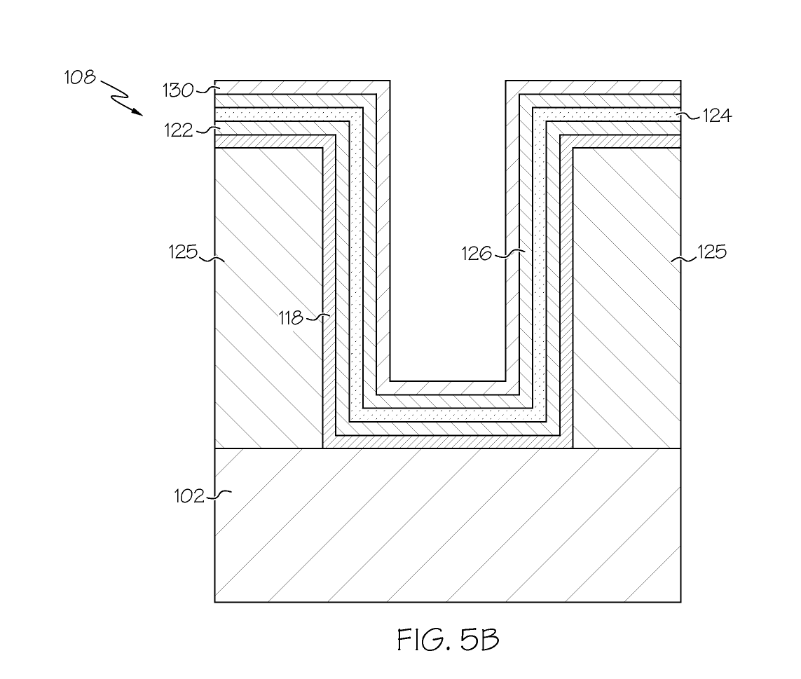

FIG. 5A is a semiconductor structure 106 after a subsequent process step of depositing a metal layer 130 in the N-type region. FIG. 5A shows a cross section as viewed along line A-A′ (see FIG. 1). Metal layer 130 serves as the N-type work function metal for the N-type region of the gate. In some embodiments, metal layer 130 may be comprised of titanium carbide (TiC), titanium aluminide (TiAl), tantalum aluminide (TaAl₃), or hafnium aluminide (HfAI or HfAl₃), or metal silicide. Metal layer 130 may be deposited via atomic layer deposition, chemical vapor deposition (CVD), or other suitable technique. FIG. 5B is a semiconductor structure after a subsequent process step of depositing a metal layer 130 in the P-type region. FIG. 5B shows a cross section as viewed along line B-B′ (see FIG. 1). The second titanium nitride layer 126 serves as the P-type work function metal, and metal layer 130 is deposited on top of metal layer 126, which serves as the P-type work function layer (126).

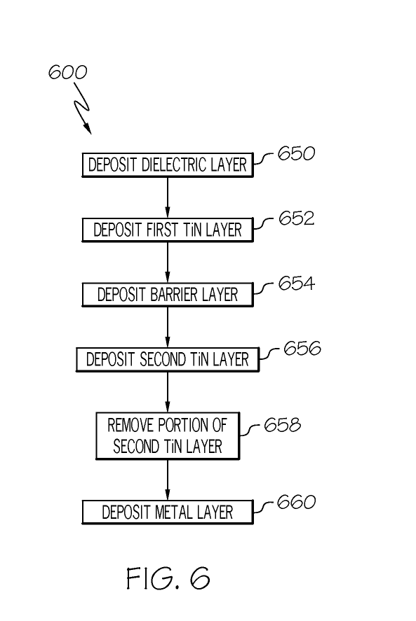

FIG. 6 is a flowchart 600 indicating process steps in accordance with illustrative embodiments. In process step 650, a dielectric layer is deposited. In process step 652, a first titanium nitride layer is deposited. In process step 654, a barrier layer is deposited. In process step 656, a second titanium nitride layer is deposited. In process step 658, a portion of the second titanium nitride layer is removed. In process step 660, a metal layer is deposited.

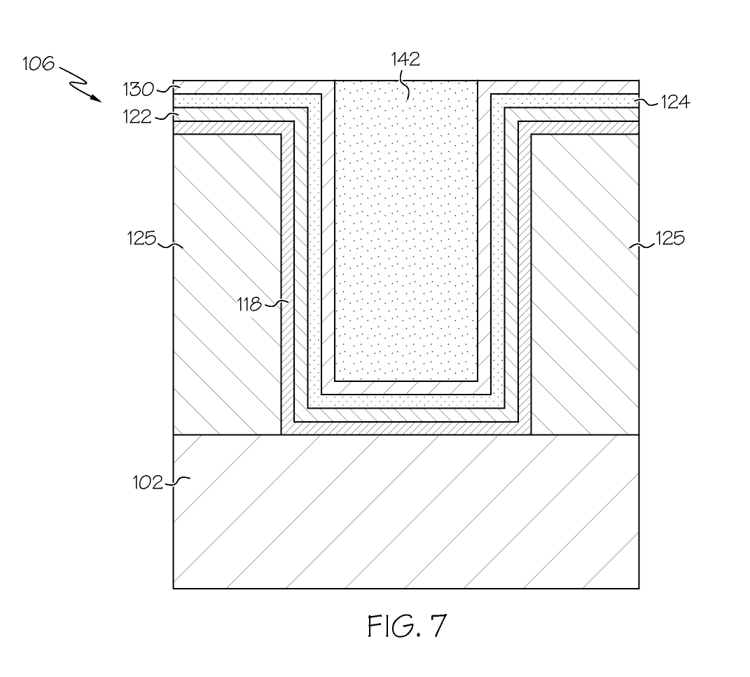

FIG. 7 is a cross-section view (as viewed along line A-A′ of FIG. 1) of an N-type region 106 in accordance with illustrative embodiments. Embodiments of the present invention are utilized in a replacement metal gate (RMG) process. The dielectric layer 118, unoxidized titanium nitride layer 122, barrier layer 124, and N-type work function metal 130 may be deposited via a conformal deposition process in a trench structure formed by dielectric regions 125. Dielectric regions 125 may be made of nitride. The unoxidized titanium nitride layer 122 is protected by barrier layer 124 during the fabrication process. Metal fill layer 142 is then deposited. In some embodiments, the metal fill layer 142 may be made of tungsten. In other embodiments, aluminum or cobalt may be used, which serve as a low resistance metal.

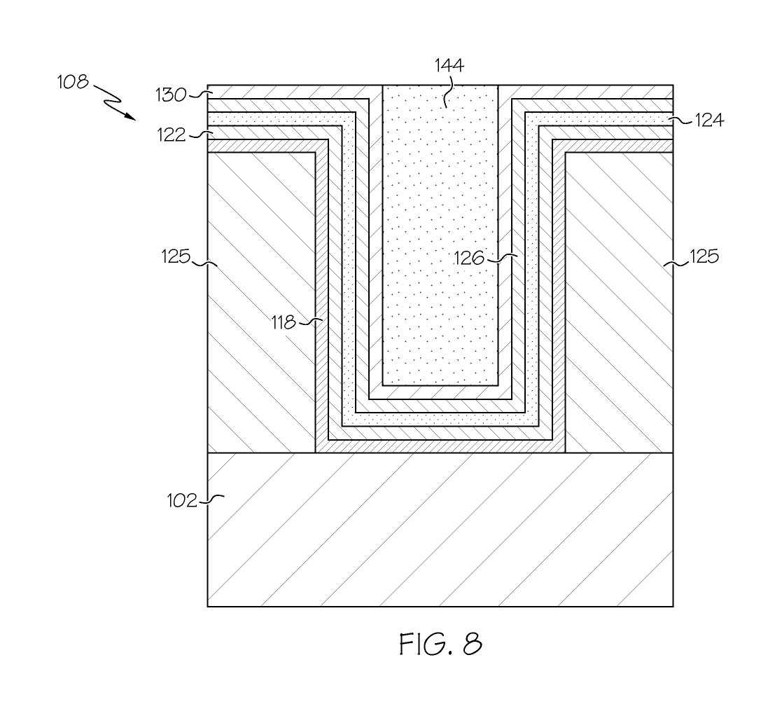

FIG. 8 is a cross-section view (as viewed along line B-B′ of FIG. 1) of a P-type region 108 in accordance with illustrative embodiments. Embodiments of the present invention are utilized in a replacement metal gate (RMG) process. The dielectric layer 118, unoxidized titanium nitride layer 122, barrier layer 124, and P-type work function metal 126 may be deposited via a conformal deposition process in a trench structure formed by dielectric regions 125. Metal layer 130 may be deposited over the P-type work function metal prior to depositing metal fill layer 144. Dielectric regions 125 may be made of nitride. The unoxidized titanium nitride layer 122 is protected by barrier layer 124 during the fabrication process. Metal fill layer 144 is then deposited. In some embodiments, the metal fill layer 144 may be formed of the same material as metal fill layer 142 of FIG. 7, or may be formed of a different material in some embodiments.

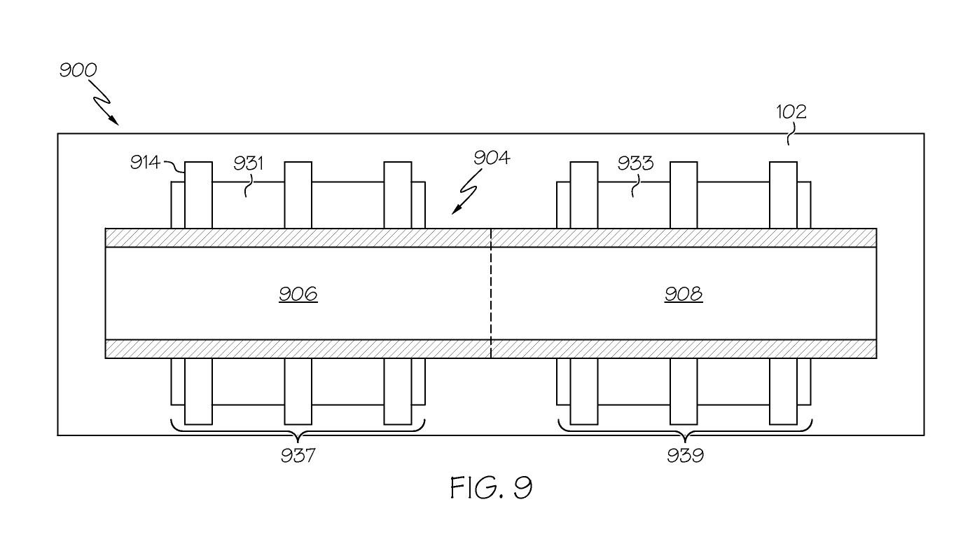

FIG. 9 is a top-down view of a semiconductor structure 900 including finFETs in accordance with illustrative embodiments. Gate region 904 includes N-type region 906 and P-type region 908. A plurality of fins 914 is formed orthogonal to the long axis of gate region 904. One or more of the fins 914 may be merged with epitaxial semiconductor regions 931 and 933. FinFET 937 is an N-type finFET and finFET 939 is a P-type finFET.

In various embodiments, design tools can be provided and configured to create the datasets used to pattern the semiconductor layers as described herein. For example, data sets can be created to generate photomasks used during lithography operations to pattern the layers for structures as described herein. Such design tools can include a collection of one or more modules and can also include hardware, software, or a combination thereof. Thus, for example, a tool can be a collection of one or more software modules, hardware modules, software/hardware modules, or any combination or permutation thereof. As another example, a tool can be a computing device or other appliance on which software runs or in which hardware is implemented. As used herein, a module might be implemented utilizing any form of hardware, software, or a combination thereof. For example, one or more processors, controllers, application-specific integrated circuits (ASIC), programmable logic arrays (PLA)s, logical components, software routines or other mechanisms might be implemented to make up a module. In implementation, the various modules described herein might be implemented as discrete modules or the functions and features described can be shared in part or in total among one or more modules. In other words, as would be apparent to one of ordinary skill in the art after reading this description, the various features and functionality described herein may be implemented in any given application and can be implemented in one or more separate or shared modules in various combinations and permutations. Even though various features or elements of functionality may be individually described or claimed as separate modules, one of ordinary skill in the art will understand that these features and functionality can be shared among one or more common software and hardware elements, and such description shall not require or imply that separate hardware or software components are used to implement such features or functionality.

While embodiments of the invention have been particularly shown and described in conjunction with exemplary embodiments, it will be appreciated that variations and modifications will occur to those skilled in the art. For example, although the illustrative embodiments are described herein as a series of acts or events, it will be appreciated that the present invention is not limited by the illustrated ordering of such acts or events unless specifically stated. Some acts may occur in different orders and/or concurrently with other acts or events apart from those illustrated and/or described herein, in accordance with the invention. In addition, not all illustrated steps may be required to implement a methodology in accordance with the present invention. Furthermore, the methods according to the present invention may be implemented in association with the formation and/or processing of structures illustrated and described herein as well as in association with other structures not illustrated. Therefore, it is to be understood that the appended claims are intended to cover all such modifications and changes that fall within the true spirit of embodiments of the invention.

1. A semiconductor structure, comprising:
a semiconductor substrate;
a dielectric layer disposed on the semiconductor substrate;
an unoxidized titanium nitride layer disposed on, and in direct physical contact with the dielectric layer;
a hafnium carbide barrier layer disposed on, and in direct physical contact with the unoxidized titanium nitride layer; and
a second titanium nitride layer disposed on, and in direct physical contact with the barrier layer.

2. The semiconductor structure of claim 1, wherein the dielectric layer is comprised of hafnium oxide.

3. The semiconductor structure of claim 1, wherein the dielectric layer is comprised of lanthanum oxide.

4. The semiconductor structure of claim 1, wherein the barrier layer is comprised of a carbon-containing material.

5. (canceled)

6. (canceled)

7. The semiconductor structure of claim 1, wherein the unoxidized titanium nitride layer has a thickness ranging from about 5 angstroms to about 15 angstroms.

8. The semiconductor structure of claim 1, wherein the barrier layer has a thickness ranging from about 5 angstroms to about 15 angstroms.

9. (canceled)

10. (canceled)

11. A gate structure comprising:
an N-type region;
a P-type region; wherein the N-type region and the P-type region comprises:
a semiconductor substrate;
a dielectric layer disposed on the semiconductor substrate;
a first titanium nitride layer disposed on, and in direct physical contact with the dielectric layer, wherein the first titanium nitride layer is unoxidized;
a hafnium carbide barrier layer disposed on, and in direct physical contact with the first titanium nitride layer; and
wherein the N-type region further comprises an N-type metal disposed on the barrier layer; and
wherein the P-type region further comprises a second titanium nitride layer disposed on, and in direct physical contact with the barrier layer.

12. The gate structure of claim 11, wherein the dielectric layer is comprised of hafnium oxide.

13. The gate structure of claim 11, wherein the dielectric layer is comprised of lanthanum oxide.

14. (canceled)

15. (canceled)

16. (canceled)

17. The gate structure of claim 11, wherein the first titanium nitride layer has a thickness ranging from about 5 angstroms to about 15 angstroms.

18. The gate structure of claim 11, wherein the barrier layer has a thickness ranging from about 5 angstroms to about 15 angstroms.

19. A method of fabricating a gate structure, comprising:
depositing a dielectric layer on a semiconductor substrate;
depositing a first titanium nitride layer on the dielectric layer;
depositing a carbon-containing barrier layer on the first titanium nitride layer;
depositing a second titanium nitride layer on the carbon-containing barrier layer;
removing a portion of the second titanium nitride layer to form an N-type region; and
depositing a metal layer in the N-type region.

20. The method of claim 19, wherein depositing a carbon-containing barrier layer on the first titanium nitride layer comprises depositing tantalum carbide.
